(19) United States
(12) Patent Application Publication
(10) Pub. No.: US 2023/0054426 A1
(43) Pub. Date: Feb. 23, 2023

(54) READ-WRITE METHOD

(71) Applicant: CHANGXIN MEMORY TECHNOLOGIES, INC., Hefei City, Anhui (CN)

(72) Inventors: Shuliang NING, Hefei City, Anhui (CN); Jun HE, Hefei City, Anhui (CN); Jie LIU, Hefei City, Anhui (CN); Zhan YING, Hefei City, Anhui (CN)

(21) Appl. No.: 17/439,068

(22) PCT Filed: Jun. 7, 2021
(86) PCT No.: PCT/CN2021/098715

§ 371 Date: Sep. 14, 2021

(30) Foreign Application Priority Data
Sep. 30, 2020 (CN) 202011056684.9

(51) Int. Cl. G06F 3/06

(52) U.S. Cl. CPC G06F 3/0659; G06F 3/0619; G06F 3/0673

(57) ABSTRACT

The present disclosure provides a read-write method. The read-write method includes: when a write operation is performed on a memory, a number of first values and a number of second values in data to be written are determined; and if the number of first values is greater than the number of second values in the data to be written, the data to be written is inverted and then stored, and an identification bit is allocated, the identification bit stores a first mark to identify the data to be written.

### CROSS-REFERENCE TO RELATED APPLICATIONS

The present disclosure claims the priority to Chinese Patent Application 202011056684.9, titled “READ-WRITE METHOD”, filed on Sep. 30, 2020, which is incorporated herein by reference in its entirety.

### TECHNICAL FIELD

The present disclosure relates to, but is not limited to, a read-write method.

### BACKGROUND

Dynamic Random Access Memory (DRAM) is a semiconductor memory. Its main principle is to use the difference in charges stored in a capacitor to represent whether a binary bit is 1 or 0.

DRAM is usually arranged in a two-dimensional matrix with a capacitor and a transistor as a unit. The basic operation mechanism is divided into read and write. During reading, the transistor is turned on to read data stored in the capacitor. During writing, the transistor is turned on to store data in the capacitor.

In reality, the transistor and/or the capacitor may leak electricity, which may change the amount of charges stored in the capacitor that stores charges to cause read errors of data, so that the reliability of the memory is reduced.

### SUMMARY

The following is the summary of subject matters detailed in the present disclosure. The summary is not intended to limit the protection scope of the claims.

The present disclosure provides a read-write method, when a write operation is performed on a memory, a number of first values and a number of second values in data to be written are determined; and if the number of first values is greater than the number of second values in the data to be written, the data to be written is inverted and then stored, and an identification bit is allocated, the identification bit stores a first mark to identify the data to be written.

Other aspects will be apparent upon reading and understanding the accompanying drawings and detailed descriptions.

### BRIEF DESCRIPTION OF THE DRAWINGS

The accompanying drawings incorporated into the description and constituting a part of the description illustrate the embodiments of the present disclosure, and are used together with the description to explain the principles of the embodiments of the present disclosure. In these drawings, similar reference numerals are used to indicate similar elements. The drawings in the following description are some embodiments of the present disclosure, but not all embodiments. For those of ordinary skill in the art, other drawings can be obtained based on these drawings without any creative efforts.

FIG. 1 is a flowchart of a read-write method according to a first embodiment of the present disclosure;

FIGS. 2A, 2B and 3 show comparison tables of data to be written and stored data in the read-write method according to the present disclosure;

FIG. 4 is a flowchart of a second embodiment of the read-write method according to the present disclosure;

FIG. 5 is a flowchart of a third embodiment of the read-write method according to the present disclosure;

FIG. 6 is a flowchart of a fourth embodiment of the read-write method according to the present disclosure;

FIG. 7 is a flowchart of a fifth embodiment of the read-write method according to the present disclosure.

### DETAILED DESCRIPTION

In order to make the objectives, technical solutions and advantages of the present disclosure clearer, the following clearly and completely describes the technical solutions in the embodiments of the present disclosure with reference to the accompanying drawings in the embodiments of the present disclosure. Apparently, the described embodiments are only part of the embodiments of the present disclosure, not all of them. All other embodiments obtained by those skilled in the art based on the embodiments of the present disclosure without any creative efforts shall fall within the protection scope of the present disclosure. It should be noted that the embodiments in the present disclosure and the features in the embodiments can be combined with each other on a non-conflict basis.

Specific embodiments of a read-write method provided by the present disclosure will be described below with reference to the accompanying drawings.

FIG. 1 is a flowchart of a read-write method according to a first embodiment of the present disclosure. Referring to FIG. 1, the read-write method includes the following steps:

When a write operation is performed on a memory, a number of first values and a number of second values in data to be written are determined. That is, whether a number of first values is greater than a number of second values in data to be written is determined.

The first value and the second value are binary numbers 1 and 0 indicating a storage state of charges stored in the memory.

The first value and the second value may be defined according to the stability of the storage state of the memory. Specifically, due to different storage principles, some memories are more stable when their storage state is the binary number 1, then the first value may be defined as the binary number 0, and the second value may be defined as the binary number 1. Some memories (such as DRAM) are more stable when their storage state is the binary number 0, then the first value may be defined as the binary number 1, and the second value may be defined as the binary number 0. A basic memory cell of DRAM includes a transistor and a capacitor. The capacitor has two plates, one of which is a common plate, the potential is half a power supply voltage (VCC/2) (0 V or other voltage values in other embodiments), and the other plate is separately connected to the corresponding transistor. When the voltage applied to the plate connected to the transistor is the power supply voltage (VCC), the binary number 1 is used to indicate a storage state of charges stored in the memory; and when the voltage applied to the plate connected to the transistor is 0 V, the binary number 0 is used to indicate a storage state of charges stored in the memory. In this embodiment, the first value is defined as the binary number 1 and the second value is defined as the binary number 0.

The number of first values refers to how many first values are in the data to be written, and the number of second values refers to how many second values are in the data to be written. For example, if the data to be written is 8-bit data 10010010, then in the data to be written, the number of first values (i.e. binary numbers 1) is 3, and the number of second values (i.e. binary numbers 0) is 5. For another example, the data to be written is 8-bit data 10111101, then in the data to be written, the number of first values (i.e. binary numbers 1) is 6, and the number of second values (i.e. binary numbers 0) is 2.

If the first values are more than the second values in the data to be written, that is, the number of first values is greater than the number of second values, the data to be written is inverted and then stored, and an identification bit is allocated, the identification bit stores a first mark to identify the data to be written.

The inversion refers to change the first value to the second value and change the second value to the first value. For example, if the first value is a binary number 1, the first value becomes a binary number 0 after inversion, and if the second value is a binary number 0, the second value becomes a binary number 1 after inversion.

Before the inversion, the number of first values is greater than the number of second values in the data to be written, then after the data to be written before the inversion is stored in the memory, because the number of capacitors whose storage states are the first values is greater than the number of capacitors whose storage states are the second values, the leakage current of the capacitors has a relatively large impact on the memory; after the data to be written is inverted, the number of second values is greater than the number of first values in the inverted data to be written, then after the inverted data to be written is stored in the memory, because the number of capacitors whose storage states are the second values is greater than the number of capacitors whose storage states are the first values, the impact of the leakage current of the capacitors on the memory is reduced, which greatly reduces data storage errors, improves the reliability of data storage, and improves the storage performance of the memory.

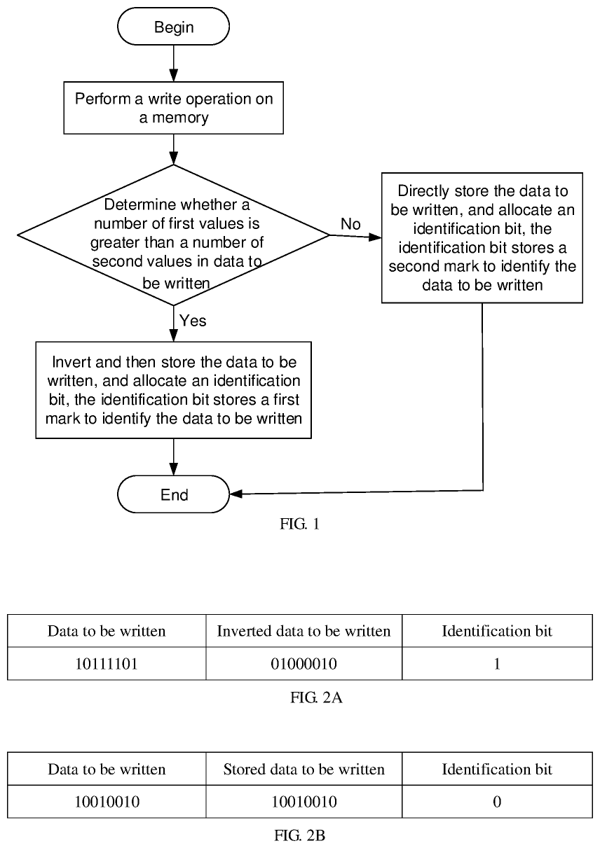

For example, referring to FIG. 2A, the data to be written is 8-bit data 10111101. In the data to be written, the number of first values (i.e. binary numbers 1) is 6, the number of second values (i.e. binary numbers 0) is 2, the number of first values is greater than the number of second values, the number of capacitors whose storage states are the first values (6) is greater than the number of capacitors whose storage states are the second values (2), and the leakage current of the capacitors has a relatively large impact on the memory; the data to be written is inverted and stored, the inverted data to be written is 01000010, the number of first values (i.e. binary numbers 1) is 2, the number of second values (i.e. binary numbers 0) is 6, the number of second values is greater than the number of first values, the number of capacitors whose storage states are the second values (6) is greater than the number of capacitors whose storage states are the first values (2), and the impact of the leakage current of the capacitors on the memory is reduced, which greatly reduces data storage errors, improves the reliability of data storage, and improves the storage performance of the memory.

An identification bit is allocated to the inverted data to be written, the identification bit being used to identify whether the data to be written is inverted. A first mark is stored in the identification bit, the first mark being used to identify the stored data to be written as the inverted data.

The value of the first mark may be determined according to actual design. For example, in this embodiment, the first mark may be a binary number 1, while in other embodiments of the present disclosure, the first mark may also be a binary number 0. For example, continuing to refer to FIG. 2A, the first mark stored in the identification bit of the inverted data to be written is a binary number 1, that is, the data of the identification bit is a binary number 1, indicating that the stored data to be written is the data after the original data to be written is inverted.

If the number of second values is greater than the number of first values in the data to be written, the data to be written is directly stored, and an identification bit is allocated, the identification bit stores a second mark to identify the data to be written.

If the second values are more than the first values in the data to be written, that is, the number of first values is less than the number of second values, then after the data to be written is stored in the memory, because the number of capacitors whose storage states are the second values is greater than the number of capacitors whose storage states are the first values, the leakage current of the capacitors has little impact on the memory. Therefore, the data to be written does not need to be inverted. If the data to be written is inverted, the impact of the leakage current of the capacitors on the memory increases instead.

For example, referring to FIG. 2B, the data to be written is 8-bit data 10010010. In the data to be written, the number of first values (i.e. binary numbers 1) is 3, the number of second values (i.e. binary numbers 0) is 5, the number of second values is greater than the number of first values, then after the data to be written is stored in the memory, the number of capacitors whose storage states are the second values (5) is greater than the number of capacitors whose storage states are the first values (3), the leakage current of the capacitors has little impact on the memory, so the inversion is not required. If the data to be written is inverted, the inverted stored data to be written is 01101101, the number of first values (i.e. binary numbers 1) is 5, the number of second values (i.e. binary numbers 0) is 3, the number of first values is greater than the number of second values, the number of capacitors whose storage states are the first values (5) is greater than the number of capacitors whose storage states are the second values (3), and the impact of the leakage current of the capacitors on the memory increases instead. Therefore, if the number of second values is greater than the number of first values in the data to be written, the data to be written is directly stored without the inversion.

An identification bit is allocated to the data to be written, the identification bit being used to identify whether the data to be written is inverted. A second mark is stored in the identification bit, the second mark being used to identify that the stored data to be written is original data, that is, non-inverted data.

The second mark and the first mark have different values to distinguish the inverted data to be written and the non-inverted data to be written. For example, in this embodiment, the first mark is a binary number 1, and the second mark is a binary number 0. In other embodiments of the present disclosure, the first mark is a binary number 0, and the second mark is a binary number 1. For example, continuing to refer to FIG. 2B, the second mark stored in the identification bit of the data to be written is a binary number 0, that is, the data of the identification bit is a binary number 0, indicating that the stored data to be written is the original data to be written.

The read-write method of the present disclosure reduces the impact of the leakage current of the capacitors on the memory by inverting the data to be written, so that data storage errors are greatly reduced, the reliability of data storage is improved, and the storage performance of the memory is improved.

During a write operation, all the data to be written in the write operation can be regarded as a whole to determine a number of first values and a number of second values in the data to be written, or all the data to be written in the write operation are divided into several groups to determine the data to be written in each group.

The data to be written is divided into several groups, and a number of first values and a number of second values in each group of data to be written are determined; if the number of first values is greater than the number of second values in the group of data to be written, the group of data to be written is inverted and then stored, and an identification bit is allocated, the identification bit stores a first mark to identify the group of data to be written; and if the number of second values is greater than the number of first values in the group of data to be written, the group of data to be written is directly stored, and an identification bit is allocated, the identification bit stores a second mark to identify the group of data to be written.

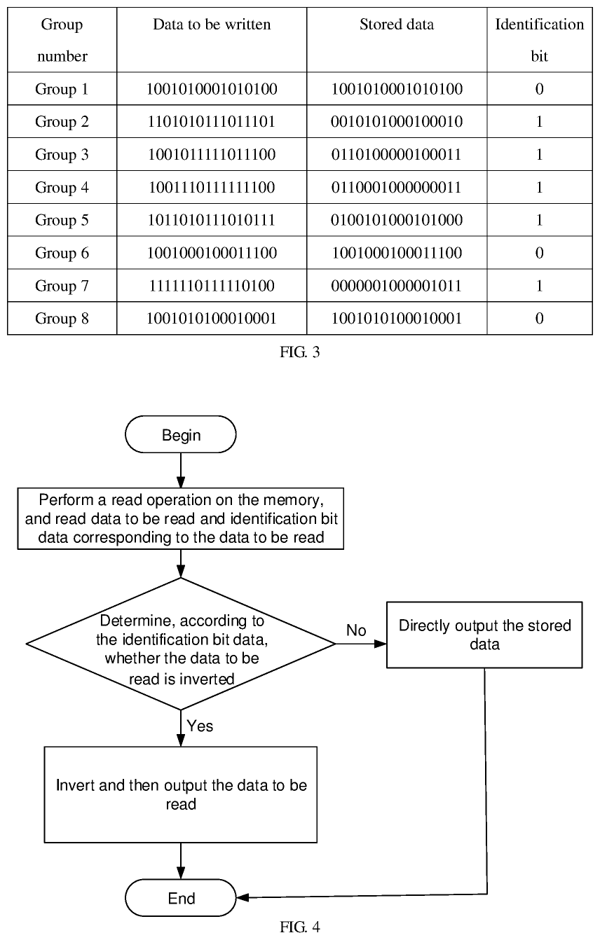

For example, referring to FIG. 3, a comparison table of data to be written and stored data is shown. In a write operation, all the data to be written are 128 bits, then the 128 bits of data to be written are divided into 8 groups, each group has 16 bits of data to be written, and a number of first values and a number of second values in each group of data to be written are determined. If the number of first values is greater than the number of second values in the group of data to be written, the group of data to be written is inverted and then stored, and an identification bit is allocated, the identification bit stores a first mark to identify the group of data to be written. Exemplarily, in the second, third, fourth, fifth and seventh groups of data to be written, the number of first values is greater than the number of second values, these group of data to be written are inverted and then stored, and an identification bit is allocated to each group, the identification bit stores a binary number 1. If the number of second values is greater than the number of first values in the group of data to be written, the group of data to be written is directly stored, and an identification bit is allocated, the identification bit stores a second mark to identify the group of data to be written. Exemplarily, in the first, sixth and eighth groups of data to be written, the number of second values is greater than the number of first values, these group of data to be written are directly stored, and an identification bit is allocated, the identification bit stores a binary number 0.

It can be understood that the number of groups of the data to be written can be set according to actual requirements, for example, the data to be written is divided into 2 groups, 4 groups, 8 groups, 16 groups, etc. It can be understood that the smaller the amount of data to be written in each group is, the less the impact of the leakage current of the capacitors on the memory is, and the higher the reliability is. In a limit case, each data to be written is a separate group, which can minimize the impact of the leakage current of the capacitors on the memory and improve the reliability. However, since an identification bit needs to be allocated to each group, as the number of groups increases, the identification bits increase, and more storage space will be occupied. As a result, the storage space of the memory is reduced. Therefore, the number of groups can be set according to the actual situation to balance the storage space and reliability of the memory.

In some embodiments, the number of data to be written included in each group of data to be written is the same as the number of data pins of the memory, then the data can be directly read from the data pins during a read operation, and the identification bits can be read from mark pins of the memory, so the logic structure is simple and the method is easy to implement. The mark pins may be DBI (data bus inversion) pins or DMI (data mask inversion) pins among existing DRAM pins.

In some embodiments, the number of data to be written included in each group of data to be written may be different from the number of data pins of the memory. For example, the number of data included in each group of data to be written is a multiple of the number of data pins of the memory.

In some embodiments, the read-write method further includes a read operation. When a read operation is performed on the memory, data to be read and identification bit data corresponding to the data to be read are read and outputted. The data to be read is data stored in the memory after the write operation.

Referring to FIG. 4, a flowchart of a second embodiment of the read-write method according to the present disclosure is shown. In the second embodiment, when a read operation is performed on the memory, data to be read and identification bit data corresponding to the data to be read are read, and an output operation is performed. The output operation includes: determining, according to the identification bit data, whether the data to be read is inverted; if the data to be read is inverted, inverting and then outputting the data to be read; and if the data to be read is not inverted, directly outputting the stored data.

During the write operation, the original data to be written may be inverted during storage. In this embodiment, the read operation needs to output the original data. Therefore, whether the data to be read is inverted is determined according to the identification bit data.

For example, when the read operation is performed on the memory, the data to be read is 01000010, and the corresponding identification bit data is a binary number 1, which indicates that the data to be read is inverted before storage, so the data to be read is inverted and then outputted as output data; when the read operation is performed on the memory, the data to be read is 10010010, and the corresponding identification bit data is a binary number 0, which indicates that the data to be read is not inverted before storage, then the stored data is directly outputted as output data.

In the second embodiment, after the read operation on the memory, since the storage state of the memory has little impact on the transmission power consumption of the memory, the original data is directly transmitted as output data, and the identification bit data does not need to be outputted. In some cases, the storage state of the memory has a relatively large impact on the power consumption of the memory, then the number of first values and the number of second values in the output data are required during low-power transmission, for example, the output data is required to have more first values or more second values. Therefore, when the read operation is performed on the memory, the output operation includes: directly outputting the data to be read as output data, or inverting all the data to be read and then outputting all the inverted data to be read as output data, and outputting the identification bit data using mark pins, or inverting the identification bit data and then outputting the inverted identification bit data using mark pins.

Referring to FIG. 5, a flowchart of a third embodiment of the read-write method according to the present disclosure is shown. In the third embodiment, when a read operation is performed on the memory, data to be read and identification bit data corresponding to the data to be read are read, the data to be read is directly outputted as output data, and the identification bit data is outputted using a mark pin, or the identification bit data is inverted and then outputted using a mark pin. In the third embodiment, after the read operation on the memory, the number of second values is required to be greater than the number of first values in the output data, but after the previous write operation, the number of second values is greater than the number of first values in the stored data, which meets the output requirements. Therefore, in this embodiment, the data to be read is not operated, but is directly outputted as output data. Meanwhile, the identification bit data is outputted using the mark pin to identify whether the output data is inverted. The mark pin may be a DBI pin or a DMI pin. In this embodiment, the identification bit data is directly used as the output data of the mark pin. In other embodiments of the present disclosure, the identification bit data can also be inverted and then outputted as the output data of the mark pin. Whether to invert the identification bit data depends on whether the meaning represented by the first mark or the second mark of the identification bit is consistent with the meaning of the output data of the mark pin; if they are consistent, the identification bit data will not be inverted; and if they are not consistent, the identification bit data will be inverted.

For example, when the read operation is performed on the memory, data to be read and identification bit data corresponding to the data to be read are read, wherein the data to be read is 01000010, the corresponding identification bit data is a binary number 1, then the data to be read is directly outputted as output data, and the identification bit data is outputted using a mark pin; the data to be read is 10010010, the corresponding identification bit data is a binary number 0, then the data to be read is directly outputted as output data. Meanwhile, if the meaning represented by the identification bit data is consistent with the meaning of the output data of the mark pin, the identification bit data is directly outputted as the output data of the mark pin.

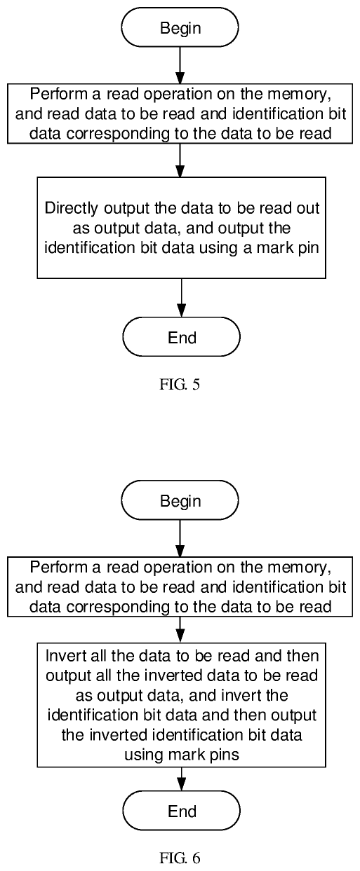

Referring to FIG. 6, a flowchart of a fourth embodiment of the read-write method according to the present disclosure is shown. In the fourth embodiment, when a read operation is performed on the memory, data to be read and identification bit data corresponding to the data to be read are read, all the data to be read are inverted and then outputted as output data, and the identification bit data are outputted using mark pins, or the identification bit data are inverted and then outputted using mark pins. In the fourth embodiment, after the read operation on the memory, the number of first values is required to be greater than the number of second values in the output data to reduce power consumption, but after the previous write operation, the number of second values is greater than the number of first values in the stored data. Therefore, in order to meet the requirements, all the data to be read are inverted and then outputted as output data during the output operation. Meanwhile, the identification bit data is outputted using the mark pins to identify whether the output data is inverted. The mark pins may be DBI pins or DMI pins. In this embodiment, the identification bit data are inverted and then used as output data of the mark pins. In other embodiments of the present disclosure, the identification bit data can also be directly used as output data of the mark pins. This embodiment is applicable to a POD (pseudo open drain)-driven DRAM memory. When the POD-driven DRAM memory transmits data, the power consumption when the storage state is 1 is significantly less than the power consumption when the storage state is 0. Therefore, the method of this embodiment can be used to achieve the purpose of reducing power consumption.

For example, when the read operation is performed on the memory, data to be read and identification bit data corresponding to the data to be read are read, and all the data to be read are inverted and outputted as output data. For example, the data to be read is 01000010, the corresponding identification bit data is a binary number 1, then the data to be read is inverted, the inverted data is 10111101, and the inverted data is outputted as output data; the data to be read is 10010010, the corresponding identification bit data is a binary number 0, then the data to be read is inverted, the inverted data is 01101101, and the inverted data is outputted as output data. Meanwhile, if the meaning represented by the identification bit data is not consistent with the traditional meaning of the output data of the mark pin, the identification bit data is inverted and then outputted as the output data of the mark pin.

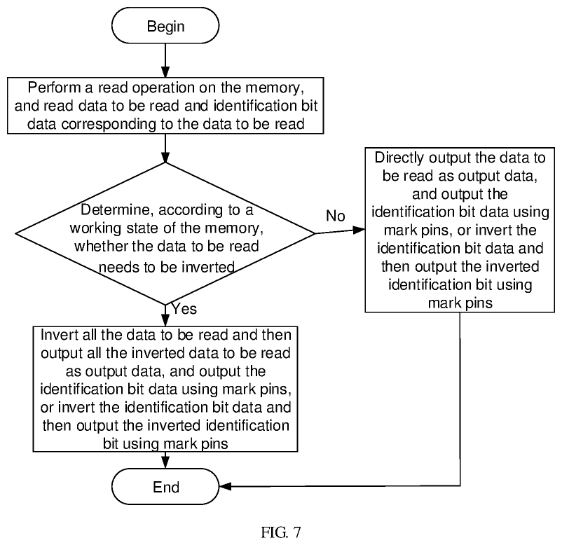

The read-write method of the present disclosure further provides a fifth embodiment. Referring to FIG. 7, a flowchart of a fifth embodiment of the read-write method according to the present disclosure is shown. In the fifth embodiment, before the output operation on the memory, whether the data to be read need to be inverted is determined according to a working state of the memory. If the data to be read need to be inverted, all the data to be read are inverted and then outputted as output data, and the identification bit data are outputted using mark pins, or the identification bit data are inverted and then outputted using mark pins. The specific operations refer to the fourth embodiment. If the data to be read do not need to be inverted, the data to be read are directly outputted as output data, and the identification bit data are outputted using mark pins, or the identification bit data are inverted and then outputted using mark pins. The specific operations refer to the third embodiment.

The working state of the memory includes a working frequency of the memory.

The read-write method of the present disclosure can adjust the stored data according to the requirements of data transmission when the read operation is performed on the memory, so as to meet the requirements of the memory and improve the performance of the memory.

A person skilled in the art would readily conceive of other embodiments of the present disclosure after considering the disclosure of the description and practice. The present disclosure is intended to cover any variations, uses or adaptive changes of the present disclosure. These variations, uses or adaptive changes follow the general principle of the present disclosure and comprise common general knowledge or conventional technical means in the technical field that are not disclosed in the present disclosure. The description and the embodiments are merely regarded as exemplary, and the real scope and spirit of the present disclosure are pointed out by the following claims.

It should be understood that the present disclosure is not limited to the precise structure described above and shown in the drawings, and various modifications and changes can be made without departing from its scope. The scope of the present disclosure is only limited by the appended claims.

### INDUSTRIAL APPLICABILITY

According to the read-write method provided by the present disclosure, a first value and a second value are defined according to the stability of the storage state of a memory, a number of first values and a number of second values in data to be written are compared, then whether the data to be written is inverted and then stored is determined according to the impact of leakage current of capacitors on the memory, and an identification bit is allocated for identification; the impact of leakage current of transistors or capacitors on the memory is reduced by inverting the data to be written, so that data storage errors are greatly reduced, the reliability of data storage is improved, and the storage performance of the memory is improved.

1. A read-write method, the read-write method comprises: when a write operation is performed on a memory, a number of first values and a number of second values in data to be written are determined; and if the number of first values is greater than the number of second values in the data to be written, the data to be written is inverted and then stored, and an identification bit is allocated, the identification bit stores a first mark to identify the data to be written.

2. The read-write method according to claim 1, wherein a number of first values and a number of second values in data to be written are determined; and if the number of second values is greater than the number of first values in the data to be written, the data to be written is directly stored, and an identification bit is allocated, the identification bit stores a second mark to identify the data to be written.

3. The read-write method according to claim 1, wherein the data to be written is divided into several groups, and a number of first values and a number of second values in each group of data to be written are determined; and if the number of first values is greater than the number of second values in a group of data to be written, the group of data to be written is inverted and then stored, and an identification bit is allocated, the identification bit stores a first mark to identify the group of data to be written.

4. The read-write method according to claim 3, wherein a number of first values and a number of second values in each group of data to be written are determined; and if the number of second values is greater than the number of first values in a group of data to be written, the group of data to be written is directly stored, and an identification bit is allocated, the identification bit stores a second mark to identify the group of data to be written.

5. The read-write method according to claim 3, wherein a number of data included in each group of data to be written is the same as a number of data pins of the memory.

6. The read-write method according to claim 3, wherein a number of data included in each group of data to be written is a multiple of a number of data pins of the memory.

7. The read-write method according to claim 2, wherein the first mark and the second mark are different values.

8. The read-write method according to claim 1, the read-write method further comprises: when a read operation is performed on the memory, data to be read and identification bit data corresponding to the data to be read are read, and an output operation is performed.

9. The read-write method according to claim 8, wherein the output operation comprises: determining, according to the identification bit data, whether the data to be read is inverted, and if the data to be read is inverted, inverting the data to be read and then outputting the inverted data to be read as output data.

10. The read-write method according to claim 8, wherein the output operation comprises: determining, according to the identification bit data, whether the data to be read is inverted, and if the data to be read is not inverted, directly outputting the stored data as output data.

11. The read-write method according to claim 8, wherein the output operation comprises: outputting the data to be read out as output data, and outputting the identification bit data using a mark pin, or inverting the identification bit data and then outputting the inverted identification bit data using a mark pin.

12. The read-write method according to claim 8, wherein the output operation comprises: inverting all the data to be read and then outputting all the inverted data to be read as output data, and outputting the identification bit data using mark pins, or inverting the identification bit data and then outputting the inverted identification bit data using mark pins.

13. The read-write method according to claim 8, wherein the output operation comprises: determining, according to a working state of the memory, whether the data to be read needs to be inverted; and if the data to be read needs to be inverted, inverting all the data to be read and then outputting all the inverted data to be read as output data, and outputting the identification bit data using mark pins, or inverting the identification bit data and then outputting the inverted identification bit using mark pins.

14. The read-write method according to claim 8, wherein the output operation comprises: determining, according to a working state of the memory, whether the data to be read needs to be inverted; and if the data to be read does not need to be inverted, outputting the data to be read as output data, and outputting the identification bit data using mark pins, or inverting the identification bit data and then outputting the inverted identification bit using mark pins.

15. The read-write method according to claim 3, the read-write method further comprises: when a read operation is performed on the memory, data to be read and identification bit data corresponding to the data to be read are read, and an output operation is performed.

16. The read-write method according to claim 15, wherein the output operation comprises: determining, according to the identification bit data, whether the data to be read is inverted, and if the data to be read is inverted, inverting the data to be read and then outputting the inverted data to be read as output data.

17. The read-write method according to claim 15, wherein the output operation comprises: determining, according to the identification bit data, whether the data to be read is inverted, and if the data to be read is not inverted, directly outputting the stored data as output data.

18. The read-write method according to claim 15, wherein the output operation comprises: outputting the data to be read out as output data, and outputting the identification bit data using a mark pin, or inverting the identification bit data and then outputting the inverted identification bit using a mark pin.

19. The read-write method according to claim 15, wherein the output operation comprises: inverting all the data to be read and then outputting all the inverted data to be read as output data, and outputting the identification bit data using mark pins, or inverting the identification bit data and then outputting the inverted identification bit using mark pins.

20. The read-write method according to claim 15, wherein the output operation comprises: determining, according to a working state of the memory, whether the data to be read needs to be inverted; and if the data to be read needs to be inverted, inverting all the data to be read and then outputting all the inverted data to be read as output data, and outputting the identification bit data using mark pins, or inverting the identification bit data and then outputting the inverted identification bit using mark pins.
